(19) United States
(12) Patent Application Publication
(10) Pub. No.: US 2020/0287051 A1
(43) Pub. Date: Sep. 10, 2020

(54) THIN FILM TRANSISTOR

(71) Applicant: AGC Inc., Chiyoda-ku (JP)

(72) Inventors: Kunio MASUMO, Tokyo (JP); Nao ISHIBASHI, Tokyo (JP); Nobuhiro NAKAMURA, Tokyo (JP); Satoru WATANABE, Tokyo (JP); Kazuto OHKOSHI, Tokyo (JP); Naomichi MIYAKAWA, Tokyo (JP)

(73) Assignee: AGC Inc., Chiyoda-ku (JP)

(21) Appl. No.: 16/878,904

(22) Filed: May 20, 2020

Related U.S. Application Data
(63) Continuation of application No. PCT/JP2018/031337, filed on Aug. 24, 2018.

(30) Foreign Application Priority Data
Nov. 28, 2017 (JP) 2017-228023

(51) Int. Cl. H01L 29/786; H01L 29/24; H01L 29/45; H01L 21/02; H01L 21/383; H01L 21/425; H01L 29/66

(52) U.S. Cl. CPC H01L 29/78618; H01L 29/24; H01L 29/45; H01L 29/66969; H01L 21/02565; H01L 21/383; H01L 21/425; H01L 29/7869

(57) ABSTRACT

A thin film transistor of a top-gate-coplanar type includes a source, a drain, a gate, and a semiconductor layer, wherein the semiconductor layer has a first low-resistance region for the source and a second low-resistance region for the drain, wherein the source and the drain are electrically connected through the first low-resistance region, the semiconductor layer, and the second low-resistance region, and wherein the semiconductor layer is formed of an oxide-based semiconductor containing gallium (Ga), zinc (Zn), and tin (Sn).

### CROSS-REFERENCE TO RELATED APPLICATIONS

This U.S. non-provisional application is a continuation application of and claims the benefit of priority under 35 U.S.C. § 365(c) from PCT International Application PCT/JP2018/031337 filed on Aug. 24, 2018, which is designated the U.S., and is based upon and claims the benefit of priority of Japanese Patent Application No. 2017-228023 filed on Nov. 28, 2017, the entire contents of which are incorporated herein by reference.

### TECHNICAL FIELD

The present disclosure relates to a thin film transistor.

### BACKGROUND ART

Conventionally, silicon has been widely used as a semiconductor material in a thin film transistor (TFT).

Recently, it has been known that, among oxide semiconductors containing metal cations, there are compounds having a relatively wide optical band gap and a relatively large mobility, and attempts are being made to apply such oxide semiconductors to a semiconductor device.

Among these, In—Ga—Zn—O-based oxide semiconductors being transparent and having characteristics comparable to amorphous silicon and low-temperature polysilicon, are attracting attention for applications to next-generation thin film transistors (see, e.g., Japanese Patent No. 5589030).

However, according to the inventors of the present application, in the case of forming a semiconductor layer based on an In—Ga—Zn—O-based oxide material (hereafter, referred to as an “IGZO material”), the semiconductor characteristics tend to decrease as the channel length shortens.

For this reason, in a thin film transistor whose semiconductor layer is formed of an IGZO material, it would be expected that shortening of the channel length of the semiconductor layer may face a limit in the future.

### SUMMARY

According to the present disclosure,

a thin film transistor of a top-gate-coplanar type is provided
that includes a source, a drain, a gate, and a semiconductor layer,
wherein the semiconductor layer has a first low-resistance region for the source and a second low-resistance region for the drain,
wherein the source and the drain are electrically connected through the first low-resistance region, the semiconductor layer, and the second low-resistance region, and
wherein the semiconductor layer is formed of an oxide-based semiconductor containing gallium (Ga), zinc (Zn), and tin (Sn).

Also, according to the present disclosure, a thin film transistor of an inverted-stagger type is provided

that includes a source, a drain, a gate, and a semiconductor layer,
wherein the source and the drain are electrically connected via the semiconductor layer, and
wherein the semiconductor layer is formed of an oxide-based semiconductor containing gallium (Ga), zinc (Zn), and tin (Sn).

### BRIEF DESCRIPTION OF DRAWINGS

FIG. 1 is a diagram schematically illustrating a cross section of a thin film transistor according to an embodiment in the present disclosure;

FIG. 2 is a diagram schematically illustrating a processing step when manufacturing a thin film transistor according to an embodiment in the present disclosure;

FIG. 3 is a diagram schematically illustrating a processing step when manufacturing a thin film transistor according to an embodiment in the present disclosure;

FIG. 4 is a diagram schematically illustrating a processing step when manufacturing a thin film transistor according to an embodiment in the present disclosure;

FIG. 5 is a diagram schematically illustrating a processing step when manufacturing a thin film transistor according to an embodiment in the present disclosure;

FIG. 6 is a diagram schematically illustrating a processing step when manufacturing a thin film transistor according to an embodiment in the present disclosure;

FIG. 7 is a diagram schematically illustrating a processing step when manufacturing a thin film transistor according to an embodiment in the present disclosure;

FIG. 8 is a diagram schematically illustrating a processing step when manufacturing a thin film transistor according to an embodiment in the present disclosure;

FIG. 9 is a diagram schematically illustrating a cross section of another thin film transistor according to an embodiment in the present disclosure;

FIG. 10 is a diagram schematically illustrating a processing step when manufacturing another thin film transistor according to an embodiment in the present disclosure;

FIG. 11 is a diagram schematically illustrating a processing step when manufacturing another thin film transistor according to an embodiment in the present disclosure;

FIG. 12 is a diagram schematically illustrating a processing step when manufacturing another thin film transistor according to an embodiment in the present disclosure;

FIG. 13 is a diagram schematically illustrating a processing step when manufacturing another thin film transistor according to an embodiment in the present disclosure;

FIG. 14 is a diagram schematically illustrating a processing step when manufacturing another thin film transistor according to an embodiment in the present disclosure;

FIG. 15 is a diagram schematically illustrating a processing step when manufacturing another thin film transistor according to an embodiment in the present disclosure;

FIG. 16 is a diagram schematically illustrating a processing step when manufacturing another thin film transistor according to an embodiment in the present disclosure;

FIG. 17 is a diagram illustrating an evaluation result of a TFT characteristic in a device A;

FIG. 18 is a diagram illustrating an evaluation result of a TFT characteristic in a device B;

FIG. 19 is a diagram illustrating an evaluation result of a TFT characteristic in a device C;

FIG. 20 is a diagram illustrating an evaluation result of a TFT characteristic in a device D;

FIG. 21 is a diagram illustrating an evaluation result of a TFT characteristic in a device E;

FIG. 22 is a diagram illustrating an evaluation result of a TFT characteristic in a device F;

FIG. 23 is a diagram illustrating an evaluation result of a TFT characteristic in a device G; and

FIG. 24 is a diagram illustrating an evaluation result of a TFT characteristic in a device H.

### EMBODIMENTS OF THE INVENTION

In the following, an embodiment in the present disclosure will be described.

According to the present disclosure, it is possible to provide a thin film transistor whose semiconductor layer is transparent, and in addition, can have a shorter channel length than a semiconductor layer formed of a conventional IGZO material.

(Thin Film Transistor of Top-Gate-Coplanar Type)

In an embodiment in the present disclosure, a thin film transistor of a top-gate-coplanar type is provided

that has a source, a drain, a gate, and a semiconductor layer,
wherein the semiconductor layer has a first low-resistance region for the source and a second low-resistance region for the drain,
wherein the source and the drain are electrically connected via the semiconductor layer, and
wherein the semiconductor layer is formed of an oxide-based semiconductor containing gallium (Ga), zinc (Zn), and tin (Sn).

Here, as a thin film transistor, a “top-gate type” means a structure in which a gate is arranged on the upper side of the semiconductor layer. As a structure contrasting to the “top gate type”, there is a structure in which a gate is arranged on the lower side of the semiconductor layer, namely, a “bottom-gate type”.

Also, a “coplanar type” means a structure in which the source, drain, and gate are arranged on the same side (e.g., upper side or lower side) with respect to the semiconductor layer. As a structure contrasting to the “coplanar type”, there is a structure in which the source and drain are arranged on a side of the semiconductor layer opposite to the other side on which the gate is arranged, namely, a “stagger type” and an “inverted-stagger type”. Note that in a “stagger type”, the gate is arranged on the upper side of the semiconductor layer, and in an “inverted-stagger type”, the gate is arranged on the lower side of the semiconductor layer.

In the present application, the “top-gate-coplanar type” means a structure in which all of the gate, source, and drain electrodes are arranged on the upper side of the semiconductor layer.

As described earlier, in a thin film transistor, in the case where an IGZO material is used for the semiconductor layer functioning as the channel between the source and the drain, as the channel length becomes shorter, the characteristics of the thin film transistor tend to be reduced. For example, in the thin film transistor, there are cases where the on/off switching characteristics reduce.

Note that the definition of the channel length will be described later.

In contrast, in an embodiment in the present disclosure, as the semiconductor layer included in a thin film transistor, an oxide-based semiconductor containing gallium (Ga), zinc (Zn), and tin (Sn) (hereafter, referred to as a “GZSO-based compound”) is used.

In the present application, the term “oxide-based” means that such a material is formed of an oxide or a compound mainly constituted with an oxide.

According to the inventors' findings, this GZSO-based compound has a feature that even in the case where the channel length is shortened, the switching characteristics are not appreciably reduced.

For this reason, in a thin film transistor whose semiconductor layer is formed of a GZSO-based compound, it is possible to significantly shorten the channel length as compared with the conventional techniques. For example, in the case where the semiconductor layer is formed of a GZSO-based compound, it is possible to provide a thin film transistor having a channel length of shorter than or equal to 5 μm, for example, a channel length of shorter than or equal to 3 μm.

Note that the reason why the characteristics are not significantly reduced even in the case where the channel length is shortened in the semiconductor layer formed of a GZSO-based compound has not been fully understood for the time being.

However, as one of the causes, it is possible to consider that a GZSO-based compound does not contain many light-absorbing substances having oxygen vacancies in the energy potential region between the valence band and the conduction band, compared to IGZO materials. However, other causes may also be considered. The mechanism is considered to become further clearer in the future.

(Thin Film Transistor According to an Embodiment in the Present Disclosure)

In the following, with reference to the drawings, an embodiment in the present disclosure will be described in further detail.

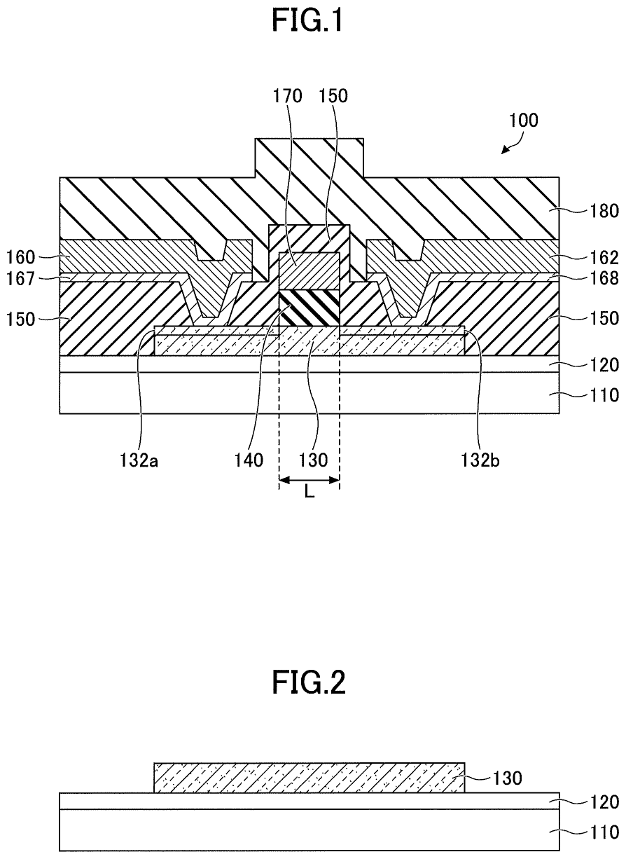

FIG. 1 schematically illustrates a cross section of a thin film transistor according to an embodiment in the present disclosure.

As illustrated in FIG. 1, in a thin film transistor (hereafter, referred to as a “first device”) 100 according to an embodiment in the present disclosure, over a substrate 110, layers of a barrier layer 120, a semiconductor layer 130, a gate insulation layer 140, a gate electrode 170, an interlayer insulation film 150, a first electrode (source or drain) 160, and a second electrode (drain or source) 162, and a passivation layer 180 are arranged and configured.

Note that it is obvious from FIG. 1 that the first device 100 is a “top-gate-coplanar type” of thin film transistor.

The substrate 110 is an insulating substrate, for example, a glass substrate, a ceramic substrate, a plastic substrate, or a resin substrate. Also, the substrate 110 may be a transparent substrate.

The barrier layer 120 is arranged between the substrate 110 and the semiconductor layer 130, and has a role of forming a back channel interface between the substrate 110 and the semiconductor layer 130. The barrier layer 120 is formed of, for example, silicon oxide, silicon oxynitride, silicon nitride, alumina, and the like. Note that the barrier layer 120 is not an essential element, and may be omitted if unnecessary.

The semiconductor layer 130 functions as an electric channel between the first electrode 160 and the second electrode 162.

The semiconductor layer 130 has a first low-resistance region 132a and a second low-resistance region 132b, on the sides of the first electrode 160 and the second electrode 162, respectively. The first low-resistance region 132a has a role of reducing contact loss between the first electrode 160 and the semiconductor layer 130. Similarly, the second low-resistance region 132b has a role of reducing contact loss between the second electrode 162 and the semiconductor layer 130.

The gate insulation layer 140 is formed of an inorganic insulating material, for example, silicon oxide, silicon oxynitride, silicon nitride, alumina, and the like. This is the same for the interlayer insulation film 150.

The first and second electrodes 160 and 162 are formed of, for example, metals such as aluminum, copper, or silver, or any other conductive materials

Note that as illustrated in FIG. 1, the first electrode 160 may include a conductive first contact layer 167. Similarly, the second electrode 162 may include a conductive second contact layer 168.

The first contact layer 167 is formed so as to directly contact the first low-resistance region 132a of the semiconductor layer 130, and the second contact layer 168 is formed so as to directly contact the second low-resistance region 132b of the semiconductor layer 130.

However, the first contact layer 167 and the second contact layer 168 are members that are arranged as necessary, and may be omitted if unnecessary.

The gate electrode 170 is formed of, for example, metals such as aluminum, copper, or silver, or any other conductive materials.

The passivation layer 180 has a role of protecting the device, and is formed of, for example, silicon oxide, silicon oxynitride, silicon nitride, alumina, and the like.

Here, in a conventional thin film transistor, a compound such as an IGZO material has been used as the semiconductor layer. However, the semiconductor layer formed of an IGZO material has a problem that it is difficult to shorten the channel length as described earlier,

In contrast, in the first device 100, a GZSO-based compound having the feature described earlier is used as the semiconductor layer 130. Therefore, in the first device 100, it is possible to significantly shorten the channel length in the semiconductor layer 130.

Here, in an embodiment in the present disclosure, the channel length means a minimum distance L between the first low-resistance region 132a and the second low-resistance region 132b. For example, in the example in FIG. 1, assuming that the first low-resistance region 132a and the second low-resistance region 132b of the semiconductor layer 130 also extend similarly in the depth direction, the distance L between the first low-resistance region 132a the second low-resistance regions 132b corresponds to the channel length.

In the first device 100, the channel length can be, for example, less than or equal to 5 μm, and further, less than or equal to 3 μm.

(Semiconductor Layer 130)

Next, the semiconductor layer 130 in the first device 100 will be described in more detail.

As described earlier, the semiconductor layer 130 is formed of a GZSO-based compound. It is favorable that the semiconductor layer 130 does not substantially contain indium (In).

A GZSO-based compound contains gallium (Ga). The atomic ratio of gallium atoms to all cation atoms is favorably in a range of 10% to 35%.

Also, a GZSO-based compound contains zinc (Zn). The atomic ratio of zinc atoms to all cation atoms is favorably in a range of 49% to 62%.

Also, a GZSO-based compound contains tin (Sn). The atomic ratio of tin atoms to all cation atoms is favorably in a range of 16% to 28%.

A GZSO-based compound contains oxygen (O) as the anion.

The semiconductor layer 130 includes the first low-resistance region 132a and the second low-resistance region 132b.

Note that whether the semiconductor layer 130 includes the first low-resistance region 132a and the second low-resistance region 132b can be easily determined by measuring the transfer characteristics of an obtained thin film transistor. Further, a special device for measuring the electric resistance of the low-resistance regions may be formed over the same substrate at the same time when forming the thin film transistor, to evaluate the resistance value.

The first low-resistance region 132a and the second low-resistance region 132b are formed by, for example, applying a resistance-lowering process to part of the surface of the semiconductor layer 130.

The resistance-lowering process may be performed by, for example, a method of applying a plasma treatment to the part of the semiconductor layer 130 with hydrogen or argon, or a method of implanting hydrogen ions into the part.

By electrically connecting the first electrode 160 and the semiconductor layer 130 via the first low-resistance region 132a, a good electrical contact can be formed between the first electrode 160 and the semiconductor layer 130. Similarly, by electrically connecting the second electrode 162 and the semiconductor layer 130 via the second low-resistance region 132b, a good electrical contact can be formed between the second electrode 162 and the semiconductor layer 130.

Here, as described earlier, the first electrode 160 may include the first contact layer 167, and the first contact layer 167 may directly contact the first low-resistance region 132a. Similarly, the second electrode 162 may include the second contact layer 168, and the second contact layer 168 may directly contact the second low-resistance region 132b.

In such a configuration, good electrical contacts can be formed relatively easily between the first electrode 160 and the semiconductor layer 130, and between the second electrode 162 and the semiconductor layer 130.

At least one of the first contact layer 167 and the second contact layer 168 may be formed of, for example, titanium (Ti) or an alloy containing Ti. In the case where the first contact layer 167 is formed of such a metal, a good ohmic contact can be obtained between the first electrode 160 and the semiconductor layer 130. The same applies to the second contact layer 168.

(Method of Manufacturing a Thin Film Transistor According to an Embodiment in the Present Disclosure)

Next, with reference to FIGS. 2 to 8, a method of manufacturing a first device 100 as illustrated in FIG. 1 will be described.

When manufacturing a first device 100, at the outset, a substrate 110 is prepared.

As described earlier, the substrate 110 may be a transparent and insulating substrate, for example, a glass substrate, a ceramic substrate, a plastic (e.g., polycarbonate or polyethylene terephthalate) substrate, or a resin substrate. The substrate 110 is thoroughly washed.

Next, if necessary, a barrier layer 120 is formed over one of the surfaces of the substrate 110.

As described earlier, the barrier layer 120 may be formed of silicon oxide, silicon oxynitride, silicon nitride, alumina, and the like.

Alternatively, as the barrier layer 120, a material having an ultraviolet-absorbing function, such as zinc oxide, may be used. In this case, ultraviolet light entering the first device 100 can be absorbed.

The method of forming the barrier layer 120 is not limited in particular. The barrier layer 120 may be deposited using various deposition techniques, for example, a sputtering method, a pulsed laser deposition method, an atmospheric-pressure CVD method, a low-pressure CVD method, a plasma CVD method, and the like. The thickness of the barrier layer 120 is favorably in a range of 10 nm to 500 nm.

Note that as described earlier, the barrier layer 120 is a layer formed as necessary, and may be omitted.

Next, the semiconductor layer 130 is formed over the barrier layer 120 (or the substrate 110).

The semiconductor layer 130 is formed of a GZSO-based compound described earlier. The method of forming the semiconductor layer 130 is not limited in particular. The semiconductor layer 130 may be deposited using various deposition techniques, for example, a sputtering method, a pulsed laser deposition method, an atmospheric-pressure CVD method, a low-pressure CVD method, a plasma CVD method, and the like.

The thickness of the semiconductor layer 130 is favorably in a range of 10 nm to 90 nm. If the thickness is greater than or equal to 10 nm, a satisfactory electron accumulation layer can be formed. The thickness of the semiconductor layer 130 is more favorably greater than or equal to 20 nm, and even more favorably greater than or equal to 30 nm. If the thickness of the semiconductor layer 130 is less than or equal to 90 nm, the voltage consumption in the thickness direction can be ignored. The thickness of the semiconductor layer 130 is more favorably less than or equal to 80 nm, and even more favorably less than or equal to 60 nm.

Next, the semiconductor layer 130 is patterned to form a desired pattern on the semiconductor layer 130.

As the patterning method, commonly used methods, for example, a mask deposition method and a lift-off method may be listed. Also, a method may be considered in which after having deposited the semiconductor layer 130, an island-shaped resist pattern is formed on the top, and by using the pattern as the mask, the semiconductor layer 130 is etched.

In the case of etching the semiconductor layer 130, as the etchant, a hydrochloric acid aqueous solution, an oxalic acid aqueous solution, an EDTA (ethylenediamine tetraacetic acid) aqueous solution, a TMAH (tetramethylammonium hydroxide) aqueous solution, and the like can be applied.

It is favorable to anneal the semiconductor layer 130 after the patterning (referred to as “primary annealing”). The atmosphere of the primary annealing is selected from among air; reduced pressure; oxygen; hydrogen; inert gas such as nitrogen, argon, helium, and neon; water vapor; and the like. The primary annealing temperature is favorably from 100° C. to 400° C.

FIG. 2 schematically illustrates a state in which the barrier layer 120 and the patterned semiconductor layer 130 are arranged over the substrate 110. The semiconductor layer 130 may be patterned after the primary annealing.

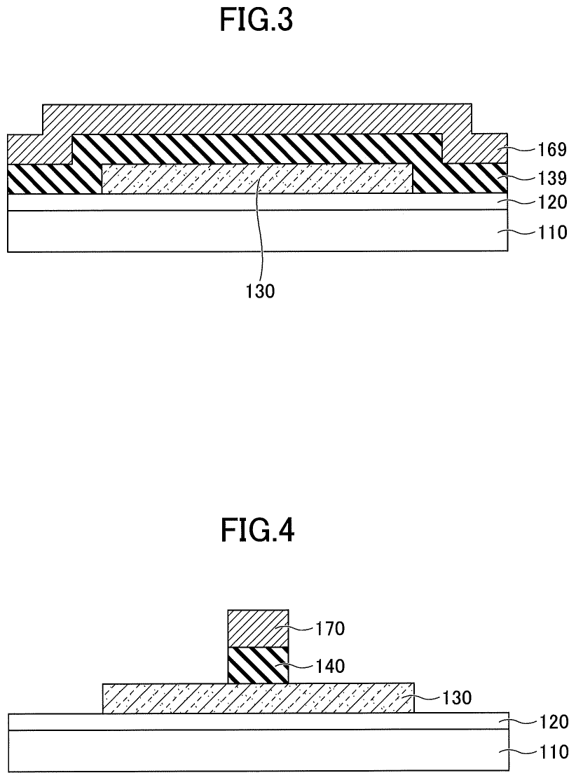

Next, as illustrated in FIG. 3, an insulation film 139 and a conductive film 169 are formed over the semiconductor layer 130.

The insulation film 139 is formed of a material that will later become a gate insulation layer 140. For example, the insulation film 139 may be formed of silicon oxide, silicon oxynitride, silicon nitride, alumina, and the like. The insulation film 139 may be deposited using a deposition technique, for example, a sputtering method, a pulsed laser deposition method, an atmospheric-pressure CVD method, a low-pressure CVD method, a plasma CVD method, and the like.

Note that before forming the insulation film 139, a plasma treatment may be applied to the surface of the semiconductor layer 130. This improves the characteristics between the semiconductor layer 130 and the insulation film 139. The plasma treatment is performed, for example, using a gas such as oxygen or dinitrogen monoxide. The plasma treatment is favorably performed before depositing the insulation film 139, by using a deposition system for the insulation film 139.

The thickness of the insulation film 139 is favorably 30 nm to 600 nm. If the thickness of the insulation film 139 is greater than or equal to 30 nm, short circuits can be controlled between the gate electrode 170 and the semiconductor layer 130. If the thickness of the insulation film 139 is less than or equal to 600 nm, a higher on-current can be obtained. The thickness of the insulation film 139 is more favorably greater than or equal to 50 nm, and even more favorably greater than or equal to 150 nm. Also, the thickness of the insulation film 139 is more favorably less than or equal to 500 nm, and even more favorably less than or equal to 400 nm.

On the other hand, the conductive film 169 is formed of a material that will later become a gate electrode 170. For example, the conductive film 169 may be formed of chromium (Cr), molybdenum (Mo), aluminum (Al), copper (Cu), silver (Ag), tantalum (Ta), titanium (Ti), or a composite material and/or alloy containing these. The conductive film 169 may be a multi-layer film.

Alternatively, as the conductive film 169, a transparent conductive film may be used. As such a transparent conductive film, for example, ITO (In—Sn—O), ZnO, AZO (Al—Zn—O), GZO (Ga—Zn—O), IZO (In—Zn—O), and SnO₂ may be listed.

The conductive film 169 may be formed by a conventional deposition method such as a sputtering method and an evaporation method. Also, the insulation film 139 and the conductive film 169 may be deposited continuously by the same deposition system.

The thickness of the conductive film 169 is favorably 30 nm to 600 nm. If the thickness of the conductive film is greater than or equal to 30 nm, a lower resistance is obtained, and if the thickness is less than or equal to 600 nm, short circuits can be controlled between the conductive film 169 and the first electrode 160 (source or drain), or between the conductive film 169 and the second electrode 162 (drain or source). The thickness of the conductive film 169 is more favorably greater than or equal to 50 nm, and even more favorably greater than or equal to 150 nm. The thickness of the conductive film 169 is more favorably less than or equal to 500 nm, and even more favorably less than or equal to 400 nm.

Next, as illustrated in FIG. 4, the insulation film 139 and the conductive film 169 are patterned, to form a gate insulation layer 140 and a gate electrode 170, respectively.

When patterning the insulation film 139 and the conductive film 169, methods used in commonly used processes, namely a combination of a commonly used photolithography process and an etching process may be used.

Next, as illustrated in FIG. 5, a first low-resistance region 132a and a second low-resistance region 132b are formed over the semiconductor layer 130.

The first low-resistance region 132a and the second low-resistance region 132b are formed by, for example, applying a resistance-lowering process to part of the semiconductor layer 130. Such a resistance-lowering process may be applied to a protruding part (see FIG. 5) protruding from the gate electrode 170 of the semiconductor layer 130 when viewed from above. In other words, the resistance-lowering process of the semiconductor layer 130 may be performed using the gate electrode 170 as the mask.

The resistance-lowering process may be performed, for example, by a method of applying a hydrogen plasma treatment or an argon plasma treatment to the protruding part, or by a method of implanting hydrogen ions into the protruding part.

In such a process, the width of the gate electrode 170 (indicated by A in FIG. 5) substantially corresponds to the channel length of the semiconductor layer 130.

As described earlier, in an embodiment in the present disclosure, the channel length of the semiconductor layer 130 can be less than or equal to 5 μm.

Next, an interlayer insulation film 150 is formed over the multi-layer film structure illustrated in FIG. 5. As described earlier, the layer interlayer insulation film 150 may be formed of silicon oxide, silicon oxynitride, silicon nitride, alumina, and the like. The interlayer insulation film 150 is deposited by a commonly used deposition technique, for example, a sputtering method, a pulsed laser deposition method, an atmospheric-pressure CVD method, a low-pressure CVD method, a plasma CVD method, and the like.

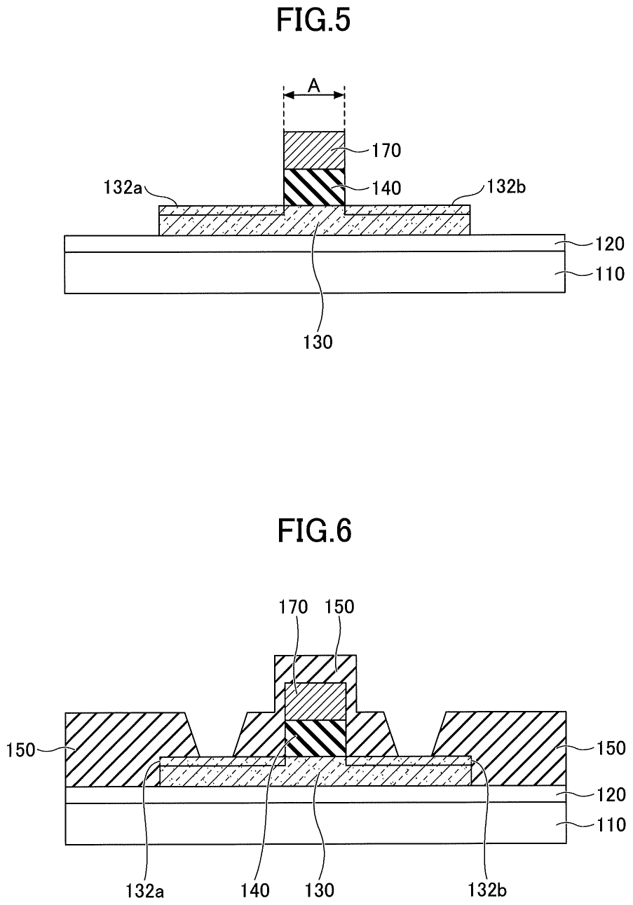

Note that as illustrated in FIG. 6, the interlayer insulation film 150 is patterned on both sides of the gate electrode 170 so as to expose part of the first low-resistance region 132a and part of the second low-resistance region 132b of the semiconductor layer 130. When patterning the interlayer insulation film as such, a combination of a commonly used photolithography process and an etching process may be used.

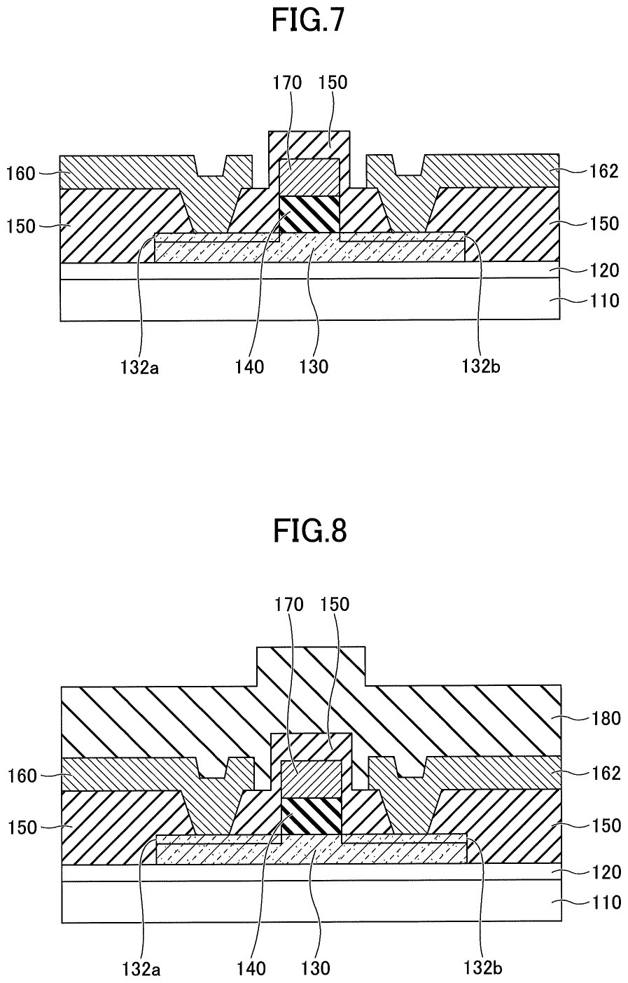

Next, as illustrated in FIG. 7, a first electrode 160 and a second electrode 162 are formed and patterned. The first and second electrodes 160 and 162 are, for example, source and drain electrodes, respectively, or vice versa.

The first electrode 160 and the second electrode 162 are formed so as to have ohmic contact with at least part of the low-resistance regions 132a and 132b of the semiconductor layer 130, to be patterned. For the patterning of the first electrode 160 and the second electrode 162, a combination of a commonly used photolithography process and an etching process may be used.

The first electrode 160 and the second electrode 162 may be formed of chromium, molybdenum, aluminum, copper, silver, tantalum, titanium, or a composite material and/or alloy containing these. Alternatively, the first electrode 160 and the second electrode 162 can be made as a transparent conductive film, similarly to the gate electrode 170.

Here, in the case of forming a first electrode 160 having a first contact layer 167 as illustrated in FIG. 1, first, a first layer for the first contact layer 167 is formed over the multi-layer film structure so as to be in contact with the first low-resistance region 132a, and the first layer is patterned. After that, a second layer is formed over the first layer, and the first electrode 160 having a two-layer structure is formed.

Similarly, in the case of forming a second electrode 162 having a second contact layer 168 as illustrated in FIG. 1, a third layer for the second contact layer 168 is formed over the multi-layer film structure so as to be in contact with the second low-resistance region 132b, and the third layer is patterned. After that, a fourth layer is formed over the third layer, and the second electrode 162 having a two-layer structure is formed.

Alternatively, the first layer and the second layer may be formed continuously and patterned together to form the first electrode 160 having the two-layer structure. The same applies to the second electrode 162 having a two-layer structure.

The first layer is favorably formed of titanium or a titanium alloy. Also, the third layer is favorably formed of titanium or a titanium alloy.

Note that if necessary, before forming the first electrode 160 (if present, the first contact layer 167), a plasma treatment may be applied to the exposed surface of the first low-resistance region 132a (hereafter, referred to as an “exposed part”). Similarly, before forming the second electrode 162 (if present, the second contact layer 168), a plasma treatment may be applied to the exposed surface of the second low-resistance region 132b.

This is to form a good contact between the first low-resistance region 132a and the first electrode 160, and between the second low-resistance region 132b and the second electrode 162. In other words, the exposed part of the first low-resistance region 132a and the second low-resistance region 132b may have a state changed due to a process such as the patterning of the interlayer insulation film 150 described earlier. By applying the plasma treatment again to the exposed part before forming the first electrode 160 and the second electrode 162, desired characteristics can be surely realized with the exposed part.

The plasma treatment applied to the exposed part is performed, for example, using a gas such as argon. The plasma treatment may be performed before depositing the electrodes (or contact layer) using a deposition system for the electrodes (or contact layer).

Next, as illustrated in FIG. 8, a passivation layer 180 is formed so as to cover the multi-layer film. The passivation layer 180 may be formed of silicon oxide, silicon oxynitride, silicon nitride, alumina, and the like.

The passivation layer 180 may be deposited using a deposition technique, such as a sputtering method, a pulsed laser deposition method, an atmospheric-pressure CVD method, a low-pressure CVD method, a plasma CVD method, and the like.

The thickness of the passivation layer 180 is favorably 30 nm to 600 nm. If the thickness of the passivation layer 180 is greater than or equal to 30 nm, the exposed electrode can be covered, and if it is less than or equal to 600 nm, the deflection of the substrate 110 due to the film stress is small. The thickness of the passivation layer 180 is more favorably greater than or equal to 50 nm, and even more favorably greater than or equal to 150 nm. Also, the thickness of the passivation layer 180 is more favorably less than or equal to 500 nm, and even more favorably less than or equal to 400 nm.

The obtained multi-layer film structure may be annealed (referred to as “secondary annealing”). The atmosphere for the secondary annealing is, for example, air. Also, the secondary annealing temperature is, for example, in a range of 200° C. to 350° C.

Through the above steps, the first device 100 can be manufactured.

Note that the above manufacturing method is merely an example, and it is apparent to those skilled in the art that the first device 100 may be manufactured by another method. For example, when the first device 100 drives a liquid-crystal or organic-electroluminescent array, auxiliary capacitance lines, terminals, and/or a current compensation circuit may be formed in addition to the above devices.

(Thin Film Transistor of Inverted-Stagger Type)

In another embodiment in the present disclosure,

a thin film transistor of the inverted-stagger type is provided
that has a source, a drain, a gate, and a semiconductor layer,
wherein the source and the drain are electrically connected via the semiconductor layer, and
wherein the semiconductor layer is formed of an oxide-based semiconductor containing gallium (Ga), zinc (Zn), and tin (Sn).

As described earlier, among thin film transistors, the “inverted-stagger type” means a structure in which the source and drain are arranged on a side of the semiconductor layer opposite to the other side on which the gate is arranged, and the gate is arranged on the lower side of the semiconductor layer.

In general, in the case of using an IGZO material for the semiconductor layer, it is difficult to form a thin film transistor of the inverted-stagger type. This is because an IGZO material does not have resistance to an etchant used when wet-etching the conductive film for electrodes. In other words, in a thin film transistor of the inverted-stagger type, it is necessary to apply wet etching to a conductive film over the upper surface of the semiconductor layer in a manufacturing process. However, during this process, the semiconductor layer is also exposed to the etchant and deteriorates.

Note that if dry etching is performed instead of wet etching in order to cope with such a problem, a problem arises that the manufacturing cost increases. Also, as described earlier, in the first place, there is a problem that it is difficult to shorten the channel length in the case of using an IGZO material for the semiconductor layer.

Due to such problems, it is difficult to realize a thin film transistor of the inverted-stagger type including a semiconductor layer formed of an IGZO material.

On the other hand, as described earlier, a GZSO-based compound has resistance to the etching solution. Therefore, in the case of using a GZSO-based compound as the semiconductor layer, a thin film transistor of the inverted-stagger type can be formed.

Also, as described earlier, a GZSO-based compound has a feature that even in the case where the channel length is shortened, the switching characteristics are not appreciably reduced.

For this reason, in a thin film transistor of the inverted-stagger type in which the semiconductor layer is formed of a GZSO-based compound, it is possible to significantly shorten the channel length as compared with the conventional techniques. For example, in the case where the semiconductor layer is formed of a GZSO-based compound, it is possible to provide a thin film transistor having a channel length of shorter than or equal to 5 μm, for example, a channel length of shorter than or equal to 3 μm.

Note that in the case of a thin film transistor of the inverted-stagger type, the channel length is determined by a minimum distance between the source and the drain.

(Another Thin Film Transistor Based on an Embodiment in the Present Disclosure)

In the following, with reference to the drawings, another embodiment in the present disclosure will be described in more detail.

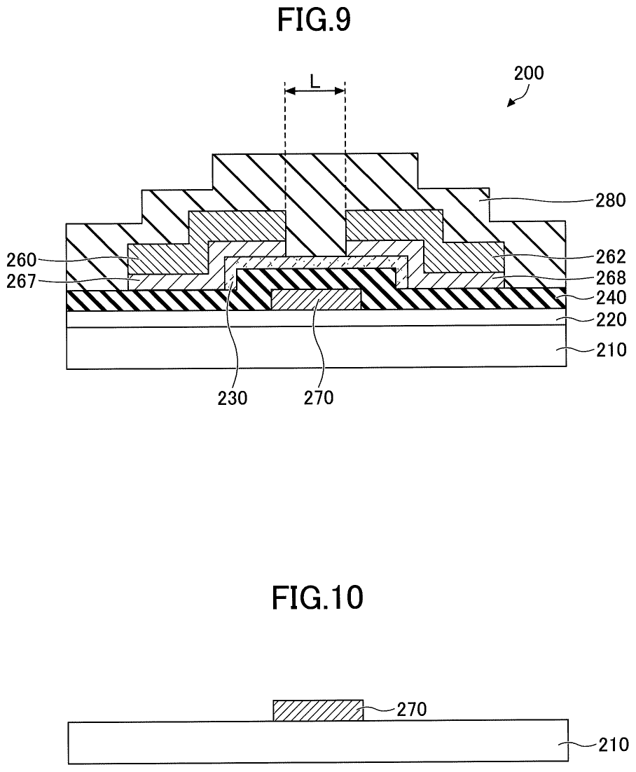

FIG. 9 schematically illustrates a cross section of the other (second) thin film transistor according to an embodiment in the present disclosure.

As illustrated in FIG. 9, in the second thin film transistor (hereafter, referred to as the “second device”) 200 according to an embodiment in the present disclosure, over a substrate 210, layers of a barrier layer 220, a gate electrode 270, a gate insulation layer 240, a semiconductor layer 230, a first electrode (source or drain) 260, and a second electrode (drain or source) 262, and a passivation layer 280 are arranged and formed.

Note that it is obvious from FIG. 9 that the second device 200 is a thin film transistor of the “inverted-stagger type”.

As illustrated in FIG. 9, the first electrode 260 may include a conductive first contact layer 267 at the bottom. Similarly, the second electrode 262 may have a conductive second contact layer 268 at the bottom.

The first contact layer 267 and the second contact layer 268 are formed so as to directly contact the semiconductor layer 230. The first contact layer 267 and the second contact layer 268 are formed of, for example, a metal such as molybdenum.

However, the first contact layer 267 and the second contact layer 268 are members that are arranged as necessary, and may be omitted if unnecessary.

Note that the specifications of members constituting the second device 200 are substantially the same as the respective members used in the first device 100 described earlier, or reference can be made to the descriptions of the respective members in the first device 100 described earlier. Therefore, such matters will not be described further here.

In the second device 200, as the semiconductor layer 230, a GZSO-based compound having the feature described earlier is used. Therefore, also in the second device 200, it is possible to significantly shorten the channel length.

Here, in the second embodiment in the present disclosure, the channel length means a minimum distance L between the first electrode 260 and the second electrode 262. For example, in the example in FIG. 9, assuming that the first electrode 260 and the second electrode 262 also extend similarly in the depth direction, the distance L between the first electrode 260 and the second electrode 262 corresponds to the channel length.

In the second device 200, the channel length can be, for example, less than or equal to 5 μm, and further, less than or equal to 3 μm.

Note that as described earlier, it is favorable that the semiconductor layer 230 does not substantially contain indium (In).

(Method of Manufacturing Another Thin Film Transistor Based on an Embodiment in the Present Disclosure)

Next, with reference to FIGS. 10 to 16, a method of manufacturing a second element 200 as illustrated in FIG. 9 will be described.

When manufacturing a second device 200, at the outset, a second substrate 210 is prepared. The specifications of the substrate 210 are as described earlier.

Next, if necessary, a barrier layer 220 is formed over one of the surfaces of the substrate 210. The method of forming the barrier layer 220 is not limited in particular. The barrier layer 220 may be deposited using various deposition techniques, for example, a sputtering method, a pulsed laser deposition method, an atmospheric-pressure CVD method, a low-pressure CVD method, a plasma CVD method, and the like.

However, the barrier layer 220 may be omitted.

Next, as illustrated in FIG. 10, a patterned gate electrode 270 is formed over the substrate 210 (or over the barrier layer 220, if present; the same shall apply hereafter).

The gate electrode 270 is formed by depositing a conductive film for the gate electrode 270 over the substrate 210, and then, by patterning the conductive film. The conductive film may be formed of, for example, chromium (Cr), molybdenum (Mo), aluminum (Al), copper (Cu), silver (Ag), tantalum (Ta), titanium (Ti), or a composite material and/or alloy containing these. Also, the conductive film may be a multi-layer film.

Note that in the second device 200, there is no need to shield the semiconductor layer 230 from light; therefore, a transparent conductive film may be used as the conductive film for the gate electrode 270.

As such a transparent conductive film, for example, ITO (In—Sn—O), ZnO, AZO (Al—Zn—O), GZO (Ga—Zn—O), IZO (In—Zn—O), and SnO₂ may be listed.

The conductive film may be deposited by a conventional deposition method such as a sputtering method or an evaporation method. Also, in the case of the barrier layer 220 being present, the barrier layer 220 and the conductive film may be continuously deposited by the same deposition system.

The film thickness of the conductive film is favorably 30 nm to 600 nm. If the film thickness of the conductive film is greater than or equal to 30 nm, a lower resistance is obtained, and if the film thickness is less than or equal to 600 nm, short circuits can be controlled between the conductive film and the first electrode 260 or the second electrode 262. The film thickness of the conductive film is more favorably greater than or equal to 50 nm, and even more favorably greater than or equal to 150 nm. The film thickness of the conductive film is more favorably less than or equal to 500 nm, and even more favorably less than or equal to 400 nm.

Next, the conductive film is patterned so as to form a gate electrode 270.

When patterning the conductive film, commonly used methods used in a TFT array process, namely, a combination of a commonly used photolithography process and an etching process may be used.

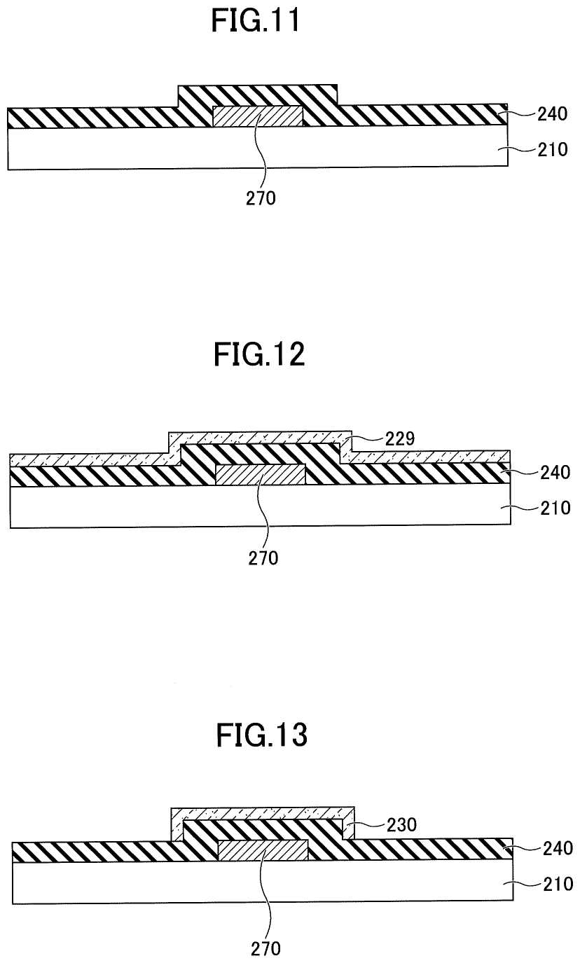

Next, as illustrated in FIG. 11, a gate insulation layer 240 is formed so as to cover the gate electrode 270.

The gate insulation layer 240 may be formed of, for example, silicon oxide, silicon oxynitride, silicon nitride, alumina, and the like. The gate insulation layer 240 may be deposited using a deposition technique, for example, a sputtering method, a pulsed laser deposition method, an atmospheric-pressure CVD method, a low-pressure CVD method, a plasma CVD method, and the like.

The thickness of the gate insulation layer 240 is favorably 30 nm to 600 nm. If the thickness of the gate insulation layer 240 is greater than or equal to 30 nm, short circuits can be controlled between the gate electrode 270 and the semiconductor layer 230, and between the gate electrode 270 and the first electrode 260 or the second electrode 262. If the thickness of the gate insulation layer 240 is less than or equal to 600 nm, a higher on-current can be obtained. The thickness of the gate insulation layer 240 is more favorably greater than or equal to 50 nm, and even more favorably greater than or equal to 150 nm. Also, the thickness of the gate insulation layer 240 is more favorably less than or equal to 500 nm, and even more favorably less than or equal to 400 nm.

Next, as illustrated in FIG. 12, a film 229 for the semiconductor layer 230 is formed.

The film 229 is formed of a GZSO-based compound described earlier. The method of forming the film 229 is not limited in particular. For example, the film 229 may be deposited using various deposition techniques such as a sputtering method, a pulsed laser deposition method, an atmospheric-pressure CVD method, a low-pressure CVD method, a plasma CVD method, and the like.

Note that the deposition of the film 229 may be performed continuously with the deposition of the gate insulation layer 240, by using a device used for the deposition of the gate insulation layer 240.

The film thickness of the film 229 is favorably in a range of 10 nm to 90 nm. If the film thickness is greater than or equal to 10 nm, a satisfactory electron accumulation layer can be formed. The film thickness of the film 229 is more favorably greater than or equal to 20 nm, and even more favorably greater than or equal to 30 nm. If the film thickness of the film 229 is less than or equal to 90 nm, concern for disconnection of the first electrode 260 or the second electrode 262 due to the steps of the film 229 can be alleviated. The film thickness of the film 229 is more favorably less than or equal to 80 nm, and even more favorably less than or equal to 60 nm.

Next, the film 229 is patterned into a desired shape to form a semiconductor layer 230 as illustrated in FIG. 13.

As the method of patterning the film 229, commonly used methods, for example, a mask deposition method and a lift-off method may be listed. Also, a method may be considered in which after having deposited the film 229, an island-shaped resist pattern is formed on the top, and by using the pattern as the mask, the film 229 is etched.

In the case of etching the film 229, as the etchant, a hydrochloric acid aqueous solution, an EDTA (ethylenediamine tetraacetic acid) aqueous solution, a TMAH (tetramethylammonium hydroxide) aqueous solution, and the like can be applied. Also, a commercially available etching solution (e.g., etching solution ITO-02, KSMF-250, and the like, manufactured by Kanto Chemical Co., Inc.) may also be used.

An organic solvent such as acetone can be used for stripping the resist, or a commercially available resist stripping solution may be used.

It is favorable to anneal the semiconductor layer 230 before the patterning or after the patterning (referred to as “primary annealing”). The atmosphere of the primary annealing is selected from among air; reduced pressure; oxygen; hydrogen; inert gas such as nitrogen, argon, helium, and neon; water vapor; and the like. The primary annealing temperature is favorably from 100° C. to 500° C.

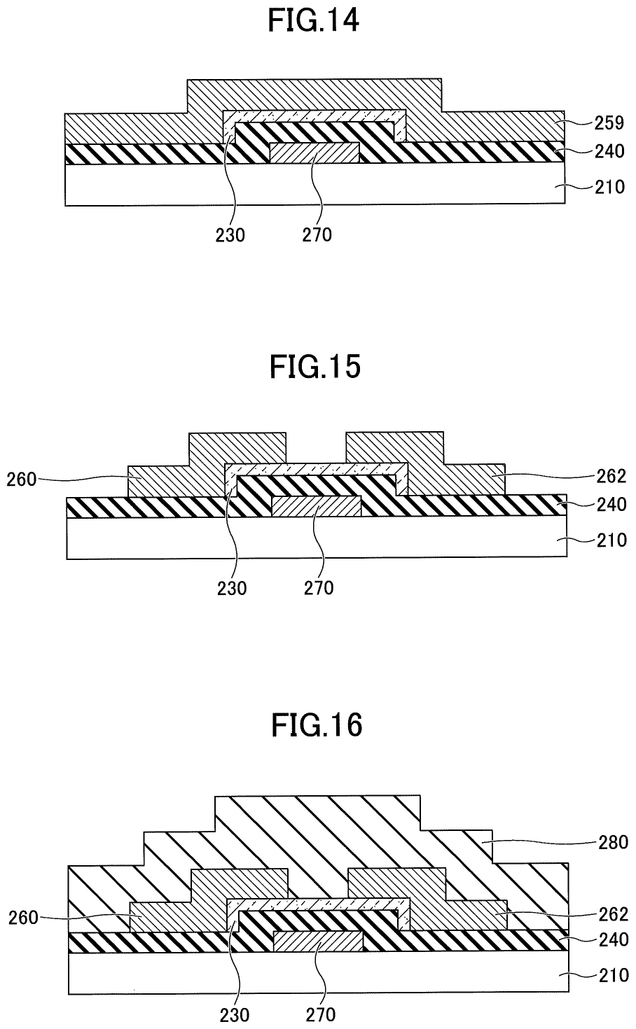

Next, as illustrated in FIG. 14, a conductive film 259 is deposited so as to cover the semiconductor layer 230.

The conductive film 259 may be formed of chromium, molybdenum, aluminum, copper, silver, tantalum, titanium, or a composite material and/or alloy containing these. Also, the conductive film 259 may be a multi-layer film. Alternatively, as the conductive film 259, a transparent conductive film may be used.

After that, as illustrated in FIG. 15, the conductive film 259 is patterned to form a first electrode 260 and a second electrode 262. When patterning the conductive film 259, a combination of a commonly used photolithography process and an etching process may be used.

The first electrode 260 and the second electrode 262 are formed so as to have ohmic contact with at least part of the semiconductor layer 230.

Note that in the case of forming the first electrode 260 having the first contact layer 267 and the second electrode 262 having the second contact layer 268 as illustrated in FIG. 9, a conductive film 259 having a two-layer structure is deposited so as to cover the semiconductor layer 230. In other words, as the conductive film 259, a conductive film 259 is deposited that includes at least a lower conductive layer and an upper conductive layer, which correspond to the first contact layer 267 and the second contact layer 268, respectively.

After that, the conductive film 259 is patterned, and the first electrode 260 having the first contact layer 267 in a state of being in contact with the semiconductor layer 230, and the second electrode 262 having the second contact layer 268 in a state of being in contact with the semiconductor layer 230, are formed.

Here, in the case of using a conventional IGZO material as the semiconductor layer 230, a problem may arise that the semiconductor layer may deteriorate during the wet patterning of the conductive film 259. This is because an IGZO material does not have resistance to an etchant used when wet-etching the conductive film 259.

However, in the second device 200, a GZSO-based compound as described earlier is used as the semiconductor layer 230. A GZSO-based compound has resistance to an etchant used when wet etching is applied to the conductive film 259. For this reason, even if the etchant contacts the semiconductor layer 230, deterioration of the semiconductor layer 230 can be controlled significantly.

Further, as described earlier, in the case of using an IGZO material for the semiconductor layer 230, as the channel length becomes shorter, the characteristics of the thin film transistor tend to be reduced. Therefore, in the case of having a semiconductor layer formed of an IGZO material, it is not possible to shorten the channel length significantly.

However, in the second device 200, the semiconductor layer 230 is formed of a GZSO-based compound; therefore, reduction in the switching characteristics can be significantly controlled even if the channel length is shortened.

For this reason, in the second device 200, it is possible to significantly shorten the channel length as compared with the conventional techniques. For example, the channel length of the semiconductor layer 230 can be less than or equal to 5 μm.

Next, a passivation layer 280 is formed. The passivation layer 280 may be formed of silicon oxide, silicon oxynitride, silicon nitride, alumina, and the like.

The passivation layer 280 may be deposited using a deposition technique such as a sputtering method, a pulsed laser deposition method, an atmospheric-pressure CVD method, a low-pressure CVD method, a plasma CVD method, and the like.

The thickness of the passivation layer 280 is favorably 30 nm to 600 nm. If the thickness of the passivation layer 280 is greater than or equal to 30 nm, the exposed electrodes can be covered, and if it is less than or equal to 600 nm, the deflection of the substrate due to the film stress is small. The thickness of the passivation layer 280 is more favorably greater than or equal to 50 nm, and even more favorably greater than or equal to 150 nm. Also, the thickness of the passivation layer 280 is more favorably less than or equal to 500 nm, and even more favorably less than or equal to 400 nm.

Before depositing the passivation layer 280, a plasma treatment may be applied to the exposed part of the semiconductor layer 230. This enables to improve the characteristics of the interface between the semiconductor layer 230 and the passivation layer 280.

Such a plasma treatment may be applied, for example, using a gas such as oxygen or dinitrogen monoxide. Also, the plasma treatment may be performed before depositing the passivation layer 280, by using a deposition system to be used when depositing the passivation layer 280.

The multi-layer film structure obtained in this way may be annealed (referred to as “secondary annealing”). The atmosphere for the secondary annealing is, for example, air. Also, the secondary annealing temperature is, for example, in a range of 200° C. to 350° C.

Through the above steps, the second device 200 can be manufactured as illustrated in FIG. 16.

Note that the above manufacturing method is merely an example, and it is apparent to those skilled in the art that the second device 200 may be manufactured by another method.

### Application Examples

Next, application examples according to the present disclosure will be described.

### Example 1

A thin film transistor (TFT) having a structure as illustrated in FIG. 1 was manufactured by the following method.

First, a barrier layer was deposited on a transparent substrate. As the transparent substrate, a non-alkali glass substrate (AN100; manufactured by Asahi Glass Co., Ltd.) having a length of 40 mm and a width of 40 mm was used. The transparent substrate was thoroughly washed with isopropyl alcohol and ultrapure water before use.

The barrier layer was formed of silicon oxide and deposited by a plasma CVD method. The thickness of the barrier layer was approximately 100 nm.

Next, a semiconductor layer was formed over the barrier layer. The semiconductor layer was a layer of a GZSO-based compound, and was deposited by a sputtering method using a target.

The target was produced as follows.

Ga₂O₃ powder, ZnO powder, and SnO₂ powder were weighed and mixed in a cation atomic % ratio of Ga:Zn:Sn=33.3:50:16.7 to prepare a mixed powder.

Next, a green compact was formed from the obtained mixed powder. Further, the green compact was sintered to obtain the target.

The deposition conditions of the semiconductor layer were as follows:

The deposition atmosphere; mixed gas of Ar and O₂ in which the O₂ concentration was 0.35%
The pressure of the deposition gas; 1 Pa
The applied power; RF 200 W
The distance between the substrate and the target; 10 cm
The target size; disc having a diameter of 50.8 mm.

The target thickness of the semiconductor layer was set to 50 nm. After the deposition, the semiconductor layer was annealed (primary annealing) at 400° C. for 1 hour in an air atmosphere.

Next, the semiconductor layer was patterned. First, an island-shaped resist pattern was arranged on the upper side of the semiconductor layer by photolithography, and by using the resist pattern as the mask, the semiconductor layer was wet-etched. An aqueous hydrochloric acid solution was used for the wet etching.

Next, an insulation film and a conductive film were sequentially deposited over the semiconductor layer.

The insulation film was made of silicon oxide and deposited by a plasma CVD method. The target thickness was 150 nm. Note that immediately before depositing the insulation film, a plasma treatment was applied to the surface of the semiconductor layer in the same device. Dinitrogen monoxide gas was used for the plasma treatment. After the plasma treatment, an insulation film was deposited.

A film of molybdenum (Mo) as the conductive film was deposited by a DC sputtering method. The target thickness was 300 nm.

Next, in order to obtain a gate electrode and a gate insulation layer, the conductive film and the insulation film were patterned. When patterning the conductive film and the insulation film, a commonly used photolithography process and an etching process were used.

After the gate electrode and the gate insulation layer were formed, a process of lowering the electric resistance (resistance-lowering process) was applied to a protruding part of the semiconductor layer protruding from the gate electrode when viewed from above. Specifically, by using a reactive ion etching (RIE) device, an argon plasma treatment was applied to the protruding part.

As a result, two low-resistance regions were formed on the surface of the semiconductor layer (see FIG. 5). The distance between the two low-resistance regions, namely, the channel length, was approximately 10 μm.

Next, an interlayer insulation film was formed over the multi-layer film structure. The interlayer insulation film was made of silicon oxide and deposited by a plasma CVD method. The target thickness was 200 nm.

After that, the interlayer insulation film was patterned. The insulation film was patterned using a commonly used photolithography process and an etching process so as to expose part of each of the low-resistance regions of the semiconductor layer on each side of the gate electrode (see FIG. 6).

Next, a first electrode (source electrode) and a second electrode (drain electrode) were formed and patterned.

Each of the first and second electrodes had a two-layer structure of a titanium layer and an aluminum layer. In other words, first, after having formed the titanium layer so as to be in contact with the low-resistance regions of the semiconductor layer, the aluminum layer was formed so as to cover the titanium layer.

Next, a passivation layer was formed so as to cover the multi-layer film structure. The passivation layer was made of silicon oxide and deposited by a plasma CVD method. The target thickness was 200 nm.

The obtained multi-layer film structure was annealed (secondary annealing) at 300° C. for 1 hour in an air atmosphere.

Through the above steps, a thin film transistor (hereafter, referred to as the “device A”) was manufactured.

### Example 2

By a method substantially the same as in Example 1, a thin film transistor (hereafter, referred to as the “device B”) was manufactured. However, in Example 2, the distance between two low-resistance regions in the semiconductor layer, namely, the channel length, was set to 5 μm.

### Example 3

By a method substantially the same as in Example 1, a thin film transistor (hereafter, referred to as the “device C”) was manufactured. However, in Example 3, the distance between the low-resistance regions in the semiconductor layer, namely, the channel length, was set to 3 μm.

### Example 4

By a method substantially the same as in Example 1, a thin film transistor (hereafter, referred to as the “device D”) was manufactured. However, in Example 4, as the semiconductor layer, an In—Ga—Zn—O-based oxide was used. The amount of indium to all cations (atomic ratio) was 33.3%, the amount of gallium to all cations (atomic ratio) was 33.3%, and the amount of zinc to all cations (atomic ratio) was 33.3%.

The other components were substantially the same as in Example 1.

### Example 5

By a method substantially the same as in Example 4, a thin film transistor (hereafter, referred to as the “device E”) was manufactured. However, in Example 4, the distance between the low-resistance regions in the semiconductor layer, namely, the channel length, was set to 5 μm.

(Evaluation)

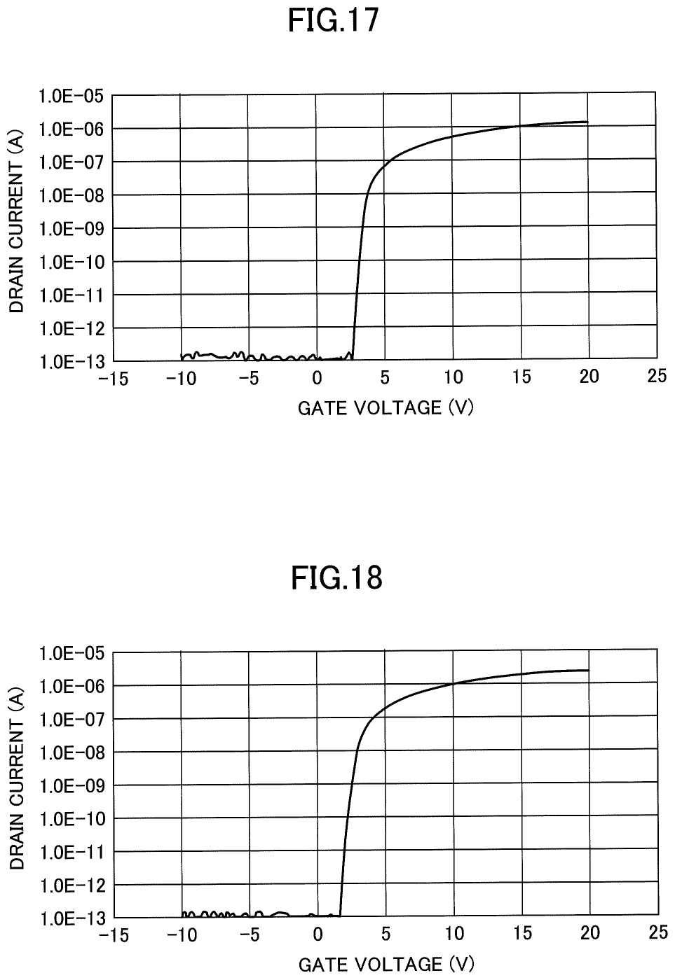

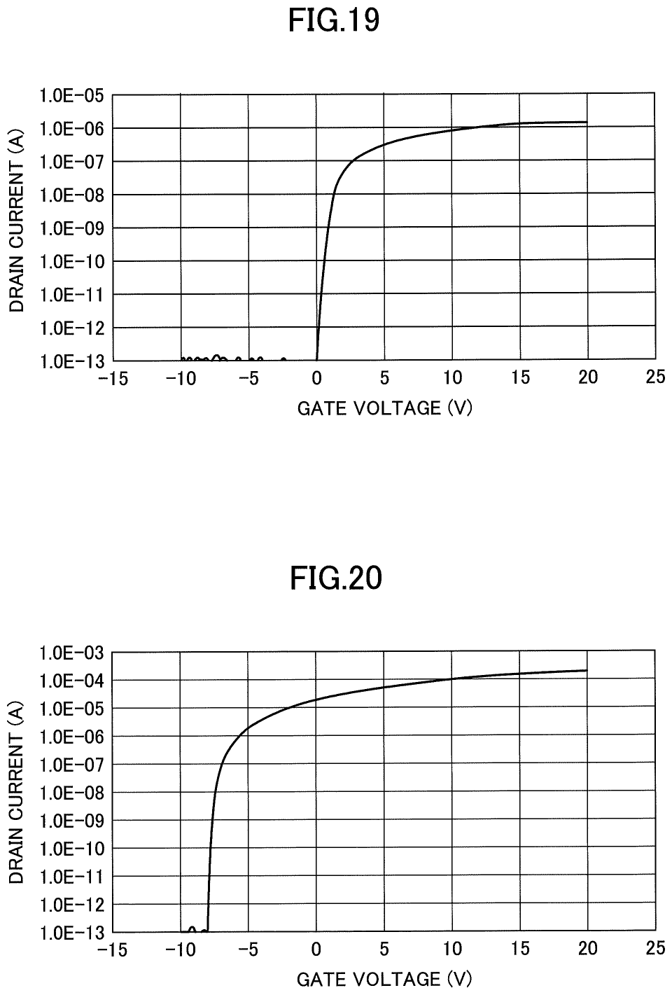

The TFT characteristics were evaluated using the above devices A to E. The obtained results are shown in FIGS. 17 to 21.

FIGS. 17 to 21 show the relationship between the gate voltage and the drain current obtained with the devices A to E, respectively.

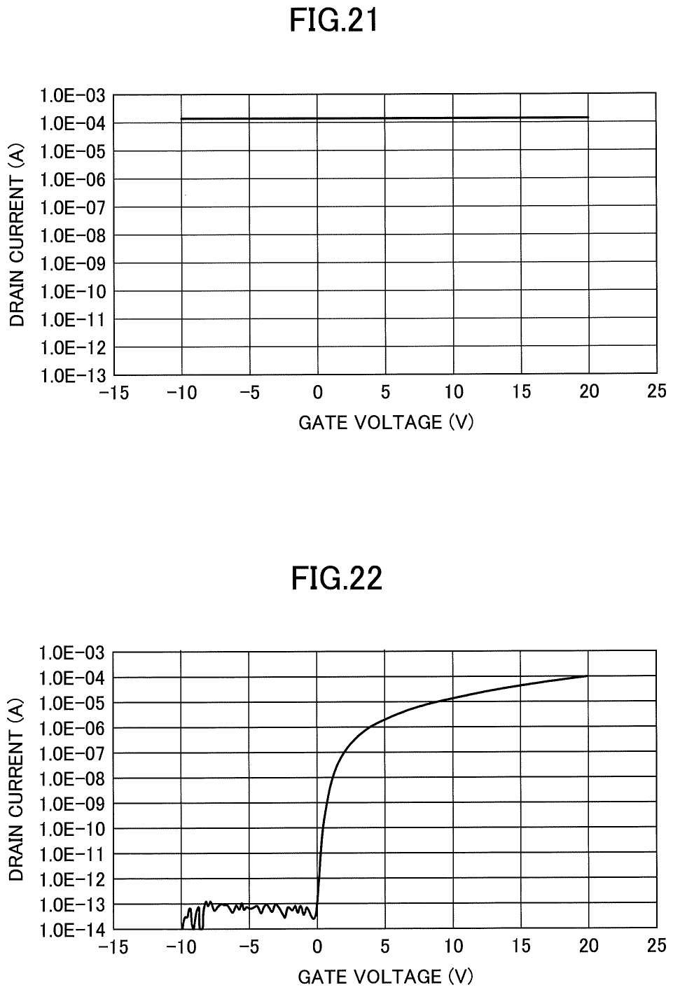

Comparing FIG. 20 with FIG. 21, it can be seen that in a device using an IGZO material as the semiconductor layer, the switching characteristics are reduced as the channel length becomes shorter. In other words, with the device D (channel length=10 μm), a certain switching characteristic could be obtained, whereas with device E (channel length=5 μm), the switching characteristic could not be obtained at all.

In this way, in a device using an IGZO material as the semiconductor layer, it can be stated that there is a tendency that it becomes difficult to obtain good characteristics as the channel length becomes shorter.

In contrast, from FIGS. 17 to 19, it can be seen that in the devices A to C using a GZSO-based compound as the semiconductor layer, even if the channel length becomes shorter to be 10 μm, 5 μm, and 3 μm, no remarkable change is observed in the characteristics. In other words, in any one of the devices A to C, good switching characteristics were obtained.

### Example 11

A thin film transistor (TFT) having a structure as illustrated in FIG. 9 was manufactured by the following method.

First, a transparent substrate was prepared. As the transparent substrate, a non-alkali glass substrate (AN100; manufactured by Asahi Glass Co., Ltd.) having a length of 40 mm and a width of 40 mm was used. The transparent substrate was thoroughly washed with isopropyl alcohol and ultrapure water before use. Note that no barrier layer was formed over the transparent substrate.

Next, over the transparent substrate, a conductive film for a gate electrode was deposited. The conductive film was formed to have a two-layer structure of a lower aluminum (Al) layer and an upper molybdenum (Mo) layer, and the film was deposited by a DC sputtering method. The target thickness of the Al layer was 50 nm, and the target thickness of the Mo layer was 50 nm.

After that, the conductive film was patterned to obtain a gate electrode. When patterning the conductive film, a commonly used photolithography process and an etching process were used.

Next, a gate insulation layer was deposited over the gate electrode. The gate insulation layer was made of silicon oxide and deposited by a plasma CVD method. The target thickness was 150 nm.

Next, a film for a semiconductor layer was deposited over the gate insulation layer. This film was made of a GZSO-based compound, and the film was deposited by a sputtering method using a target.

The target was produced as follows.

Ga₂O₃ powder, ZnO powder, and SnO₂ powder were weighed and mixed in a cation atomic % ratio of Ga:Zn:Sn=13.3:60:26.7 to prepare a mixed powder.

Next, a green compact was formed from the obtained mixed powder. Further, the green compact was sintered to obtain the target.

The deposition conditions of the film for the semiconductor layer were as follows:

The deposition atmosphere; mixed gas of Ar and O₂ in which the O₂ concentration was 0.35% The pressure of the deposition gas; 1 Pa
The applied power; RF 200 W
The distance between the substrate and the target; 10 cm
The target size; disc having a diameter of 50.8 mm.

The target thickness of the film was 50 nm. After the deposition, the film was annealed (primary annealing) at 400° C. for 1 hour in an air atmosphere.

Next, the obtained film was patterned to form a semiconductor layer. First, by photolithography, an island-shaped resist pattern is placed on the top of the film, and by using this as the mask, the film was wet-etched. For the wet etching, an etching solution ITO-02 manufactured by Kanto Chemical Co., Ltd. was used. The resist pattern was removed with a stripping solution 104 manufactured by Tokyo Ohka Kogyo Co., Ltd.

Next, a conductive film for first and second electrodes was deposited over the semiconductor layer. The conductive film had a two-layer structure of a lower Mo layer and an upper Al layer.

After that, the conductive film was patterned to form a first electrode (source) and a second electrode (drain).

The patterning was performed by a combination of a commonly used photolithography process and an etching process. When performing the etching, a mixed solution of phosphoric acid, acetic acid, and nitric acid, which has been known as a commonly used etching solution, was used. The etching process as such caused no damage to the semiconductor layer.

Note that the minimum distance between the source and drain electrodes in the semiconductor layer, namely, the channel length, was set to 10 μm.

Next, a plasma treatment was applied to the exposed part of the semiconductor layer. Dinitrogen monoxide gas was used for the plasma treatment.

In succession, in the same deposition chamber, a passivation layer was formed so as to cover the multi-layer film structure. The passivation layer was made of silicon oxide and deposited by a plasma CVD method. The target thickness was 200 nm.

The obtained multi-layer film structure was annealed (secondary annealing) at 300° C. for 1 hour in an air atmosphere.

Through the above steps, a thin film transistor (hereafter, referred to as the “device F”) was manufactured.

### Example 12

By a method substantially the same as in Example 11, a thin film transistor (hereafter, referred to as the “device G”) was manufactured. However, in Example 12, the channel length was set to 5 μm.

### Example 13

By a method substantially the same as in Example 11, a thin film transistor (hereafter, referred to as the “device H”) was manufactured. However, in Example 13, the channel length was set to 3 μm.

(Evaluation)

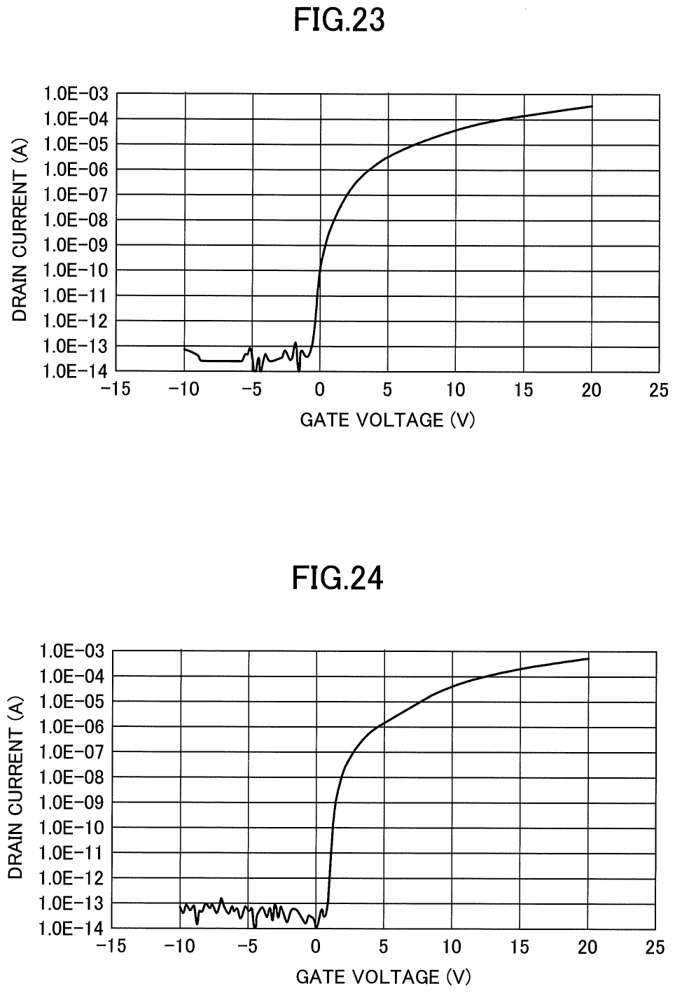

The TFT characteristics were evaluated using the above devices F to H. The obtained results are shown in FIGS. 22 to 24.

FIGS. 22 to 24 show the relationship between the gate voltage and the drain current obtained with the devices F to H, respectively.

From FIGS. 22 to 24, it can be seen that in the devices F to H using a GZSO-based compound as the semiconductor layer, even if the channel length becomes shorter to be 10 μm, 5 μm, and 3 μm, no remarkable change is observed in the characteristics. In other words, in any one of the devices F to H, good switching characteristics were obtained.

In this way, it was confirmed that the channel length of the semiconductor layer could be shortened in a thin film transistor by using a GZSO-based compound as the semiconductor layer.

1. A thin film transistor of a top-gate-coplanar type, comprising:
a source, a drain, a gate, and a semiconductor layer,
wherein the semiconductor layer has a first low-resistance region for the source and a second low-resistance region for the drain,
wherein the source and the drain are electrically connected through the first low-resistance region, the semiconductor layer, and the second low-resistance region, and
wherein the semiconductor layer is formed of an oxide-based semiconductor containing gallium (Ga), zinc (Zn), and tin (Sn).

2. The thin film transistor as claimed in claim 1, wherein referring to a minimum distance between the first low-resistance region and the second low-resistance region as a channel length, the channel length is shorter than or equal to 5 μm.

3. The thin film transistor as claimed in claim 1, wherein in the semiconductor layer, an atomic ratio of gallium atoms to all cation atoms is within a range of 10% to 35%.

4. The thin film transistor as claimed in claim 1, wherein in the semiconductor layer, an atomic ratio of zinc atoms to all cation atoms is within a range of 49% to 62%.

5. The thin film transistor as claimed in claim 1, wherein the semiconductor layer does not contain indium (In), and has an atomic ratio of tin atoms to all cation atoms being within a range of 16% to 28%.

6. The thin film transistor as claimed in claim 1, wherein the first low-resistance region is in contact with a first contact, and is connected to the source via the first contact, and
wherein the first contact is formed of a material containing titanium (Ti).

7. The thin film transistor as claimed in claim 1, wherein the second low-resistance region is in contact with a second contact, and is connected to the drain via the second contact, and
wherein the second contact is formed of a material containing titanium (Ti).

8. The thin film transistor as claimed in claim 1, wherein at least one of the first low-resistance region and the second low-resistance region is a plasma-treated region or hydrogen-ion-implanted region of the semiconductor layer.

9. A thin film transistor of an inverted-stagger type, comprising:
a source, a drain, a gate, and a semiconductor layer,
wherein the source and the drain are electrically connected via the semiconductor layer, and
wherein the semiconductor layer is formed of an oxide-based semiconductor containing gallium (Ga), zinc (Zn), and tin (Sn).

10. The thin film transistor as claimed in claim 9, wherein referring to a minimum distance between the source and the drain as a channel length, the channel length is shorter than or equal to 5 μm.

11. The thin film transistor as claimed in claim 9, wherein in the semiconductor layer, an atomic ratio of gallium atoms to all cation atoms is within a range of 10% to 35%.

12. The thin film transistor as claimed in claim 9, wherein in the semiconductor layer, an atomic ratio of zinc atoms to all cation atoms is within a range of 49% to 62%.

13. The thin film transistor as claimed in claim 9, wherein the semiconductor layer does not contain indium (In), and has an atomic ratio of tin atoms to all cation atoms being within a range of 16% to 28%.
